(19) United States
(12) Patent Application Publication
(10) Pub. No.: US 2012/0129284 A1
(43) Pub. Date: May 24, 2012

(54) METHOD FOR MANUFACTURING LIQUID CRYSTAL DISPLAY PIXEL ARRAY

(75) Inventors: Chengming HE, Shenzhen (CN); Ming-shi LEE, Shenzhen (CN)

(73) Assignee: SHENZHEN CHINA STAR OPTOELECTRONICS TECHNOLOGY CO., LTD., Shenzhen (CN)

(21) Appl. No.: 13/217,633

(22) Filed: Aug. 25, 2011

(30) Foreign Application Priority Data
Nov. 22, 2010 (CN) 201010557526.1

(51) Int. Cl. H01L 33/08

(52) U.S. Cl. 438/30; 257/E33.001

(57) ABSTRACT

This invention discloses a method for manufacturing liquid crystal display pixel array, which is capable of promoting an aperture ratio. The method of this invention includes forming a gate metal layer on a glass substrate; forming a gate insulation layer; forming a semiconductor layer; forming a second metal layer on the semiconductor layer; forming a switch region photoresist layer and a data line region photoresist layer on the second metal layer; etching the second metal layer; etching the semiconductor layer; etching the switch region photoresist layer and the data line region photoresist layer; and etching edge portions of the semiconductor in the switch region and the data line region by using fluoride-bearing gas. To etch off more edge portions of the semiconductor in the data line region, according to this invention, the thickness of the data line region photoresist layer is made thinner when forming the photoresist layer.

### TECHNICAL FIELD OF THE INVENTION

The present invention relates to a liquid crystal display (LCD) manufacturing technique, and more particularly, to a method for manufacturing LCD pixel array.

### BACKGROUND OF THE INVENTION

Nowadays, liquid crystal displays (LCDs) are becoming the main stream of displaying technique, and have been widely applied to various electronic products such as a mobile phone, a PDA, a digital camera, a computer screen, a notebook screen and the like. Amongst, a thin film transistor (TFT) LCD using a TFT as a switch for a pixel is suitable for high resolution applications, and therefore occupies an importance position.

In the TFT LCD, each pixel has a TFT as a switch. The TFT has a gate connected to a scan line, a source connected to a data line, and a drain connected to a pixel electrode. When the scan line is driven, the TFT is turned on, the data line is fed with a video signal, and the pixel electrode is charged to a proper voltage. Then the TFT is turned off until a signal is written into the next time.

A manufacturing process flow of the TFT LCD generally includes three stages: array process, cell process and module process. In the array process stage, a TFT, a storage capacitor and circuits etc. are formed on a glass substrate.

FIG. 1 to FIG. 3 show steps of a method for manufacturing TFT LCD pixel array in accordance with prior art. Each of FIG. 1 to FIG. 3 includes two portions (A) and (B), the portion (A) shows a sectional view of TFT formation (also called a switch region), and the portion (B) shows a sectional view of formation of a data line region.

The method for manufacturing TFT LCD pixel array in accordance with prior art mainly utilizes four mask processes. As shown in FIG. 1, in the method for manufacturing TFT LCD pixel array in accordance with prior art, a first metal layer is formed on a glass substrate 100 by a deposition process, and a mask is used to execute a development process. In the development process, after photoresist (not shown) is coated on the first metal layer, the photoresist is exposed by using an exposure machine according to a first mask with a specific pattern, and the exposed photoresist is cleaned out by using a developer. Then the first metal layer is subjected to an etch process. In this step, a wet etch is usually utilized. In the etch process, the first metal layer is etched by using strong acid to remove the first metal layer not covered by the photoresist, so as to form a gate metal layer 110 as shown in the drawing. After that, a gate insulation layer 120 is formed, and a semiconductor layer 130 is formed on the gate insulation layer 120. The semiconductor layer 130 is generally an amorphous Si (a-Si) layer. Then, a second metal layer 140 is formed on the semiconductor layer 130 as source/drain of a TFT. Therefore, this layer is also called a source-drain metal layer. Subsequently, a layer of photoresist 150 is coated on the source-drain metal layer 140. A mask is used to form the photoresist 150 into a required pattern by executing the exposure and development processes to the photoresist 150. As shown in FIG. 1(A), the layer of photoresist 150 includes a photoresist layer 152 (hereafter, “switch region photoresist layer”) with a general thickness in the switch region, in which a recess is correspondingly formed in the photoresist above the gate metal layer 110, this position is a location where a source-drain conductive channel 155 to be formed. That is, the source-drain conductive channel photoresist layer 154 under the bottom of the recess has a smaller thickness. In addition, as shown in FIG. 1(B), the photoresist is formed as a photoresist layer 156 (hereafter, “data line region photoresist layer) of a required pattern in the data line region.

Then, as shown in the portions (A) and (B) of FIG. 2, the second metal layer (i.e. the source-drain metal layer) 140 is etched by the patterned photoresist 150 and the portion of the second metal layer 140 not covered by the patterned photoresist 150 is removed to form a first portion 142 (i.e. the source/drain) and a second portion 146 (i.e. the data line). In this step, a wet etch process is usually utilized. Since the wet etch is a kind of isotropic etch, an undercut phenomenon will occur. That is, the periphery of the metal layer portion to be retained is somewhat etched out. Therefore, the retained metal layer portion is smaller than the covering photoresist layer, as shown in the drawing.

Then, as shown in (A) and (B) of the FIG. 3, the semiconductor layer 130 in the switch region and the data line region is etched. Dry etch is generally utilized here.

Subsequently, the layer of photoresist 150 in the switch region is etched for the purpose of removing the photoresist layer 154 to open the source-drain conductive channel 155. In addition, the layer of photoresist 150 in the data line region is etched. Dry etch is usually utilized here. Generally, oxygen (O2) is used as the etching gas.

In the prior art, the coated thickness of the photoresist 150 is consistent over the switch region and the data line region. For example, the thickness h1 of the switch region photoresist layer 152 and the thickness h2 of the data line region photoresist layer 156 are 2.2 μm. That is, before the photoresist 150 is etched, the thickness ratio h1:h2 of the photoresist provided in the switch region and the data line region is 1:1. If the etched and removed photoresist thickness h3 is 0.7 μm, then the thickness h4 of the residual switch region photoresist layer 152 and the thickness h5 of the residual data line region photoresist layer 156 are both 1.5 μm.

For the TFT manufactured by the method of the prior art, as shown in the portion (B) of FIG. 3, the finally residual semiconductor layer 136 in the data line region has a larger area, resulting in a lower aperture ratio. The aperture ratio is obtained by dividing a light permeable effective area of each pixel by the total area of the pixel. The higher the aperture ratio is, the brighter the whole picture is. Therefore, the picture will be darker if the aperture ratio is low.

### SUMMARY OF THE INVENTION

A primary objective of the present invention is to provide a method for manufacturing liquid crystal display pixel array, which is capable of promoting an aperture ratio.

To achieve the foregoing objective of the present invention, a method for manufacturing liquid crystal display pixel array is provided. The method for manufacturing liquid crystal display pixel array comprises: forming a first metal layer on a glass substrate and etching the same to form a patterned first metal layer; forming an insulation layer to cover the first metal layer and the glass substrate; forming a semiconductor layer on the insulation layer; forming a second metal layer on the semiconductor layer; forming a predetermined patterned photoresist layer on the second metal layer, the photoresist layer comprising a switch region photoresist layer and a data line region photoresist layer; etching the second metal layer to remove portions of the second metal not covered by the switch region photoresist and the data line photoresist; etching the semiconductor layer; etching the switch region photoresist layer and the data line region photoresist layer; etching edge portions of the semiconductor in the switch region and the data line region by fluoride-bearing gas.

To achieve the foregoing objective of the present invention, another method for manufacturing liquid crystal display pixel array is provided. The method for manufacturing liquid crystal display pixel array comprises: forming a first metal layer on a glass substrate and etching the same to form a patterned first metal layer; forming an insulation layer to cover the first metal layer and the glass substrate; forming a semiconductor layer on the insulation layer; forming a second metal layer on the semiconductor layer; forming a predetermined patterned photoresist layer on the second metal layer, the photoresist layer comprising a switch region photoresist layer and a data line region photoresist layer; etching the second metal layer to remove portions of the second metal not covered by the switch region photoresist and the data line photoresist; etching the semiconductor layer; etching edge portions of the semiconductor in the switch region and the data line region; etching the switch region photoresist layer and the data line region photoresist layer.

As can be known from the above, in comparison to the prior art, the present invention comprises the following advantageous effect: at the same time with or after etching the photoresist, the edge portions of the semiconductor layer in the switch region and the data line region are etched by using fluoride-bearing gas to further reduce an area of the semiconductor layer in the data line region, and thereby lifting an aperture ratio.

To make the present invention more manifest and understandable, preferred embodiments will be described in detail in conjunction with the appending drawings:

### BRIEF DESCRIPTION OF THE DRAWINGS

FIG. 1 to FIG. 3 are schematically sectional diagrams showing the respective steps of a method for manufacturing a TFT LCD pixel array in accordance with prior art, in which a portion (A) of each drawing shows a switch region, and a portion (B) shows a data line region.

FIG. 4 to FIG. 6 are schematically sectional diagrams showing the respective steps of a method for manufacturing a TFT LCD pixel array in accordance with the present invention, in which a portion (A) of each drawing shows a switch region, and a portion (B) shows a data line region.

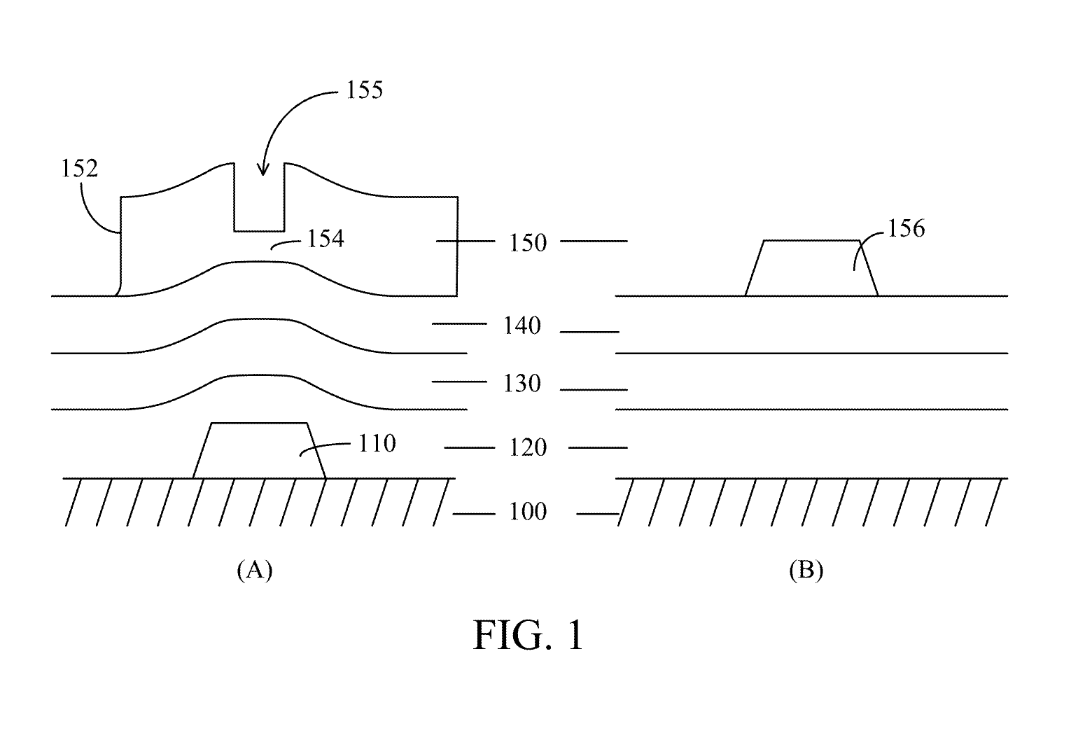

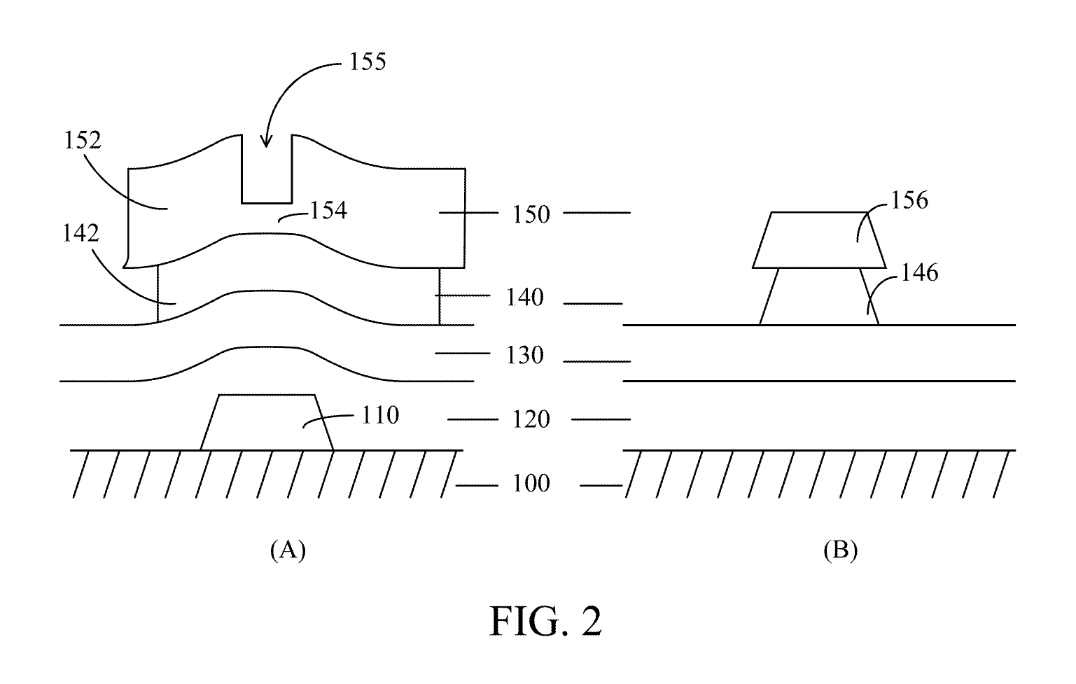

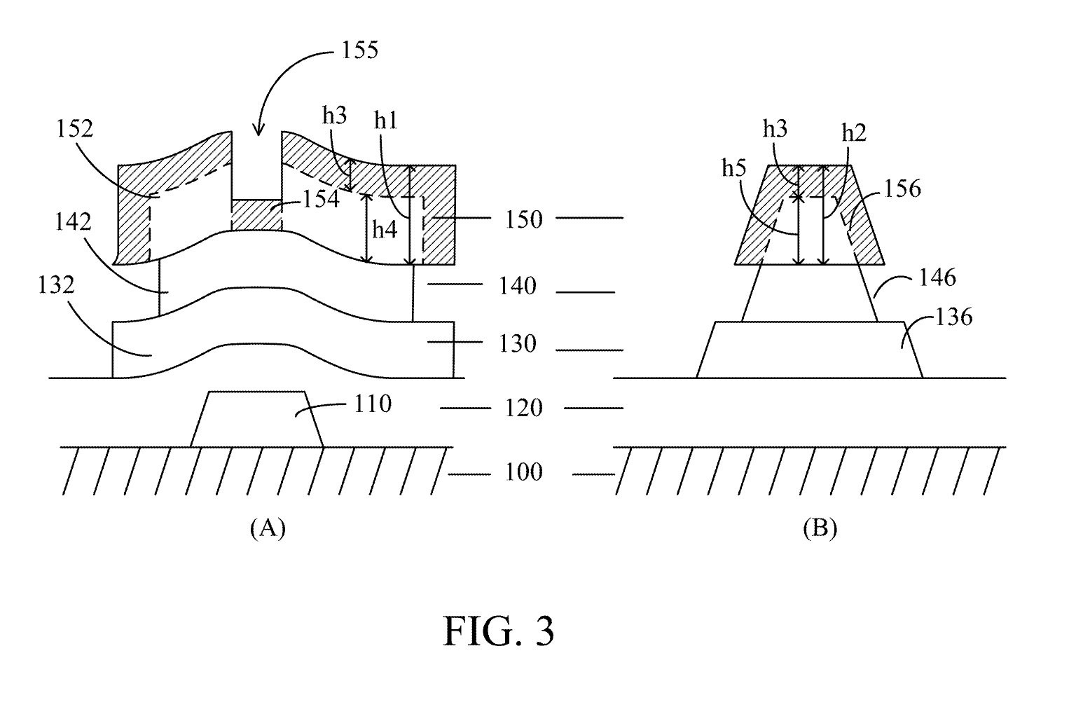

### DETAILED DESCRIPTION OF THE INVENTION

To make the forgoing objectives, features, and advantages more manifest and understandable, preferred embodiments of the present invention will be described in detail in conjunction with the appending drawings. Further, sizes shown and mentioned in the present invention such as length, width, height, thickness and the like are only used for describing and understanding the present invention rather than limiting the present invention.

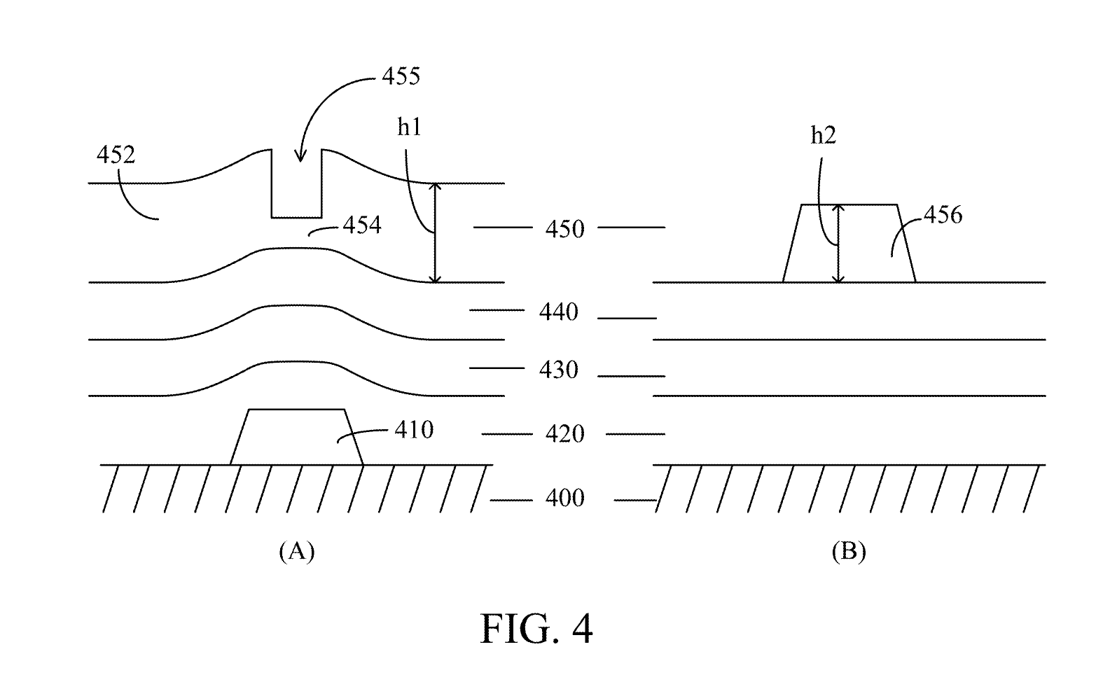

FIG. 4 to FIG. 6 are schematically sectional diagrams showing the respective steps of a method for manufacturing a TFT LCD pixel array in accordance with the present invention, in which a portion (A) of each drawing shows a switch region, and a portion (B) shows a data line region.

As shown in FIG. 4, in the method for manufacturing TFT LCD pixel array in accordance with the present invention, a first metal layer is deposited on a glass substrate 400, and a mask is used to execute a development process. In the development process, after photoresist (not shown) is coated on the first metal layer, the photoresist is exposed by using an exposure machine according to a first mask with a specific pattern, and the exposed photoresist is cleaned out by using a developer. Then the first metal layer is subjected to an etch process. In this step, a wet etch is usually utilized. In the etch process, the first metal layer is etched by using strong acid to remove the first metal layer not covered by the photoresist, so as to form a patterned first metal layer, that is, a gate metal layer 410 as shown in the drawing. After that, an insulation layer is formed to cover the gate metal layer 410 and the exposed glass substrate 400 in the switch region and the data line region by a deposition process. That is, a gate insulation layer 420 is formed. A semiconductor layer 430 is then formed on the gate insulation layer 420. The semiconductor layer 430 is generally an amorphous Si (a-Si) layer. Then, a second metal layer 440 is formed on the semiconductor layer 430 as source/drain of a TFT. Therefore, this layer is also called a source-drain metal layer. Subsequently, a layer of photoresist 450 is coated on the source-drain metal layer 440. A mask is used to form the photoresist 450 into a required pattern by executing the exposure and development processes to the photoresist 450. As shown in FIG. 4(A), the layer of photoresist 450 includes a photoresist layer 452 (hereafter, “switch region photoresist layer”) with a general thickness in the switch region, in which a recess is correspondingly formed in the photoresist above the gate metal layer 410, this position is a location where a source-drain conductive channel 455 to be formed. That is, the source-drain conductive channel photoresist layer 454 under the bottom of the recess has a smaller thickness. In addition, as shown in FIG. 4(B), the photoresist is formed as a photoresist layer 456 (hereafter, “data line region photoresist layer) of a required pattern in the data line region. It is noted that the thickness h2 of the data line region photoresist layer 456 is smaller than the thickness h1 of the switch region photoresist layer 452. For example, the thickness h1 of the switch region photoresist layer 452 is 2.2 μm, while the thickness h2 of the data line region photoresist layer 456 can be 1.8 μm. Therefore, the thickness ratio h1:h2 of the photoresist provided in the switch region and the data line region is 11:9 rather than 1:1 as in the prior art. In general, a range of the thickness ratio h1:h2 of the photoresist provided in the switch region and the data line region is preferably greater than or equal to 11:10 and less than or equal to 11:5.

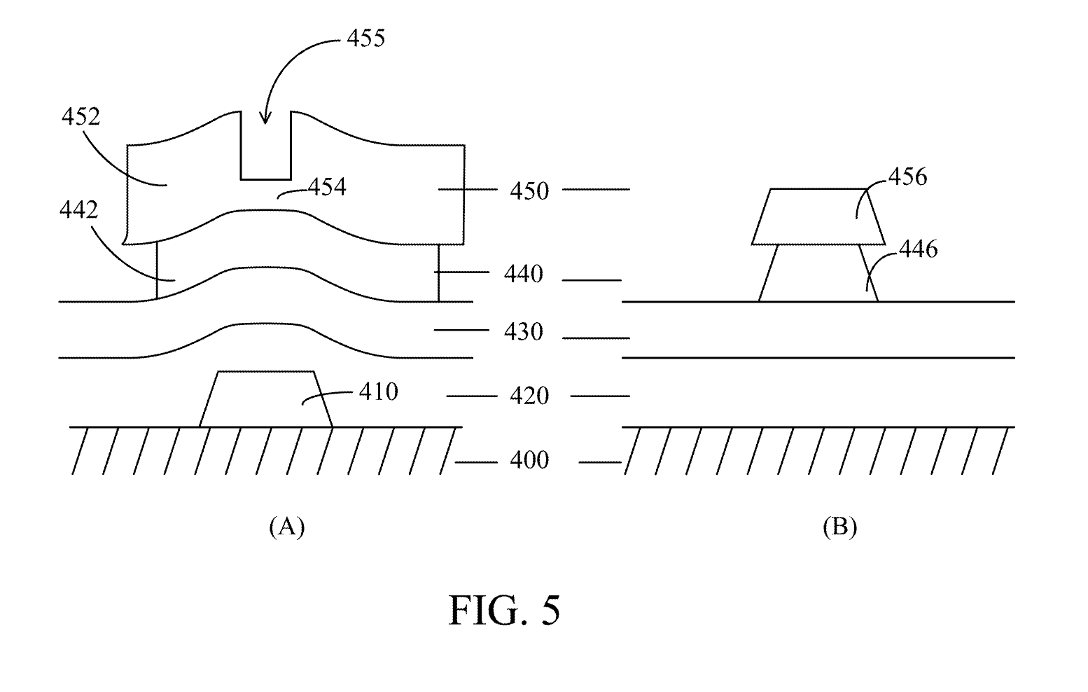

Then, as shown in the portions (A) and (B) of FIG. 5, the second metal layer (i.e. the source-drain metal layer) 440 is etched by the patterned photoresist 450, and the portion of the second metal layer 440 not covered by the patterned photoresist 450 is removed to form a first portion 442 (i.e. the source/drain) and a second portion 446 (i.e. the data line). In this step, a wet etch process is usually utilized. As mentioned above, since the wet etch is a kind of isotropic etch, an undercut phenomenon will occur, as shown in the drawing.

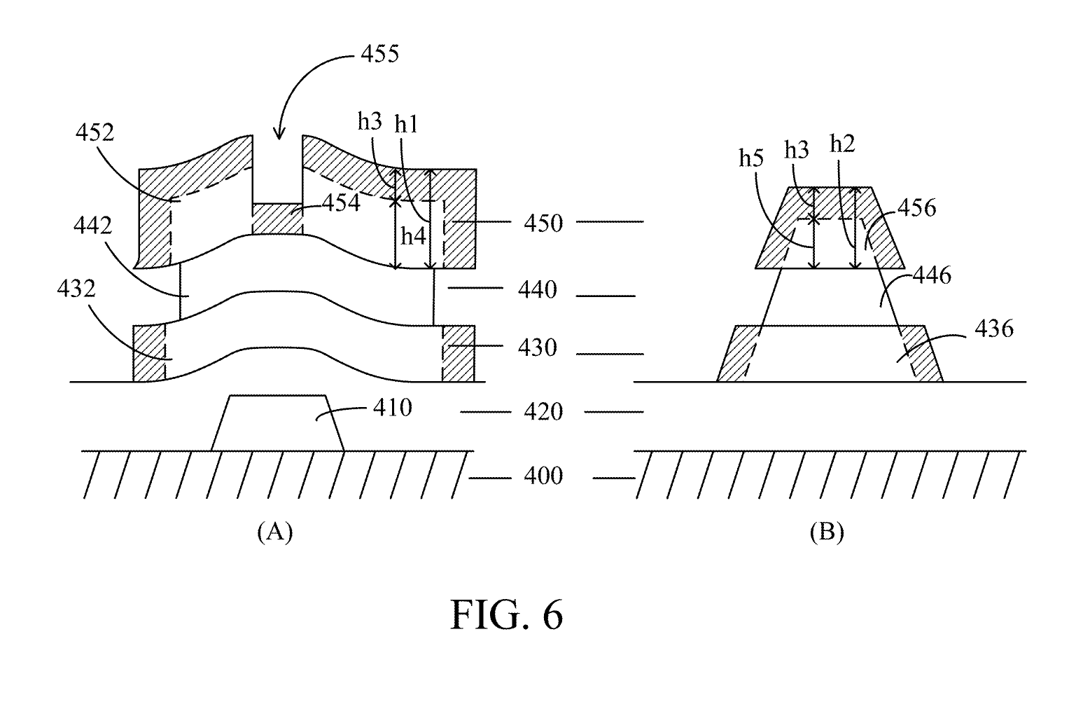

Then, as shown in (A) and (B) of the FIG. 6, the semiconductor layer 430 in the switch region and the data line region is etched. Dry etch is generally utilized here.

Subsequently, the layer of photoresist 450 in the switch region is etched for the purpose of removing the photoresist layer 454 to open the source-drain conductive channel 455. Dry etch is usually utilized here. As described above, oxygen or other proper gas can be used to partially etch the switch region photoresist layers (452, 454) and the data line region photoresist layer 456. In the embodiment of the present invention, oxygen (O2) and fluoride-bearing gas are used as the etching gases to etch the photoresist 450 and the semiconductor 430 at the same time. The fluoride-bearing gas is preferably sulfur hexafluoride (SF6) or carbon tetrafluoride (CF4). An edge portion of the semiconductor layer 436 in the data line region is etched by using fluoride-bearing gas, causing the area of the semiconductor layer 436 in the data line region becomes smaller, so that the aperture ratio can be lifted. The range of the ratio of oxygen to fluoride-bearing gas is preferably greater than or equal to 4:3 and less than or equal to 4:1, and more preferably is 2:1.

After the photoresist 450 and the edge portion of the semiconductor layer 430 are etched, the second metal layer 442 at the recess and a portion of the semiconductor layer 432 are further etched to form the drain and source. Finally, the entire switch region photoresist layer 452 is stripped. The remaining data line region photoresist layer 456 is used for protecting the second metal layer 446 below.

As shown in the drawing, the portions indicated by dashed lines and marked by shadow are the etched portions. As shown in FIG. 6, since the thickness h2 of the data line region photoresist 456 is only 1.8 μm, the thickness h4 of the residual switch region photoresist region 452 is 1.5 μm while the thickness h5 of the residual switch region photoresist region 456 is only 1.1 μm when the thickness h3 of the etched photoresist is 0.7 μm. The area of the data line region photoresist 456 is smaller than that in the prior art, so that the covered area of the semiconductor layer 436 is also smaller, and therefore the fluoride-bearing gas can touch and etch more of the edge portion of the semiconductor layer 436. In this way, the area of the data line semiconductor 436 can be further reduced to lift the aperture ratio.

From the foregoing, while the present invention has been disclosed by describing the preferred embodiments, the embodiments are not used for limiting the present invention. Various modifications and alterations can be made by persons skilled in this art without departing from the spirit and realm of the present invention, and therefore the claimed scopes of the present invention to be protected should be according to the scopes defined in the appended claims.

What is claimed is:

1. A method for manufacturing liquid crystal display pixel array, characterized in that: said method comprising:
forming a first metal layer on a glass substrate and etching the same to form a patterned first metal layer;
forming an insulation layer to cover the first metal layer and the glass substrate;
forming a semiconductor layer on the insulation layer;
forming a second metal layer on the semiconductor layer;
forming a predetermined patterned photoresist layer on the second metal layer, the photoresist layer comprising a switch region photoresist layer and a data line region photoresist layer, in which a thickness of the data line region photoresist layer is less than a thickness of the switch region photoresist layer;
etching the second metal layer;
etching the semiconductor layer;
etching the switch region photoresist layer and the data line region photoresist layer;
etching edge portions of the semiconductor in the switch region and the data line region.

2. The method according to claim 1, characterized in that, etching the switch region photoresist layer and the data line region photoresist layer comprises: using oxygen to etch the switch region photoresist layer and the data line region photoresist layer.

3. The method according to claim 1, characterized in that, etching edge portions of the semiconductor in the switch region and the data line region comprises: using fluoride-bearing gas to etch the edge portions of the semiconductor in the switch region and the data line region.

4. The method according to claim 3, characterized in that: the fluoride-bearing gas is SF6 or CF4.

5. The method according to claim 1, characterized in that: etching the switch region photoresist layer and the data line region photoresist layer and etching edge portions of the semiconductor in the switch region and the data line region comprise:
using oxygen to etch the switch region photoresist layer and the data line region photoresist layer and at the same time using fluoride-bearing gas to etch the edge portions of the semiconductor in the switch region and the data line region.

6. The method according to claim 5, characterized in that: a range of a ratio of oxygen to fluoride-bearing gas is greater than or equal to 4:3 and less than or equal to 4:1.

7. The method according to claim 1, characterized in that: a range of a ratio of the thickness of the switch region photoresist to the thickness of the data line region photoresist is greater than or equal to 11:10 and less than or equal to 11:5.

8. A method for manufacturing liquid crystal display pixel array, characterized in that: said method comprising:
forming a first metal layer on a glass substrate and etching the same to form a patterned first metal layer;
forming an insulation layer to cover the first metal layer and the glass substrate;
forming a semiconductor layer on the insulation layer;
forming a second metal layer on the semiconductor layer;
forming a predetermined patterned photoresist layer on the second metal layer, the photoresist layer comprising a switch region photoresist layer and a data line region photoresist layer;
etching the second metal layer to remove portions of the second metal not covered by the switch region photoresist and the data line photoresist;
etching the semiconductor layer;
etching the switch region photoresist layer and the data line region photoresist layer;
etching edge portions of the semiconductor in the switch region and the data line region by fluoride-bearing gas.

9. The method according to claim 8, characterized in that, etching the switch region photoresist layer and the data line region photoresist layer comprises: using oxygen to etch the switch region photoresist layer and the data line region photoresist layer.

10. The method according to claim 9, characterized in that: using oxygen to etch the switch region photoresist layer and the data line region photoresist layer and a using fluoride-bearing gas to etch the edge portions of the semiconductor in the switch region and the data line region are executed at the same time.

11. The method according to claim 10, characterized in that: a range of a ratio of oxygen to fluoride-bearing gas is greater than or equal to 4:3 and less than or equal to 4:1.

12. The method according to claim 8, characterized in that: the fluoride-bearing gas is SF6 or CF4.

13. The method according to claim 8, characterized in that: forming a predetermined patterned photoresist layer on the second metal layer, the photoresist layer comprising a switch region photoresist layer and a data line region photoresist layer comprises:
forming the predetermined patterned photoresist layer on the second metal layer, the photoresist layer comprising the switch region photoresist layer and the data line region photoresist layer, in which a thickness of the data line region photoresist layer is less than a thickness of the switch region photoresist layer

14. The method according to claim 13, characterized in that: a range of a ratio of the thickness of the switch region photoresist to the thickness of the data line region photoresist is greater than or equal to 11:10 and less than or equal to 11:5.

15. A method for manufacturing liquid crystal display pixel array, characterized in that: said method comprising:
forming a first metal layer on a glass substrate and etching the same to form a patterned first metal layer;
forming an insulation layer to cover the first metal layer and the glass substrate;
forming a semiconductor layer on the insulation layer;
forming a second metal layer on the semiconductor layer;
forming a predetermined patterned photoresist layer on the second metal layer, the photoresist layer comprising a switch region photoresist layer and a data line region photoresist layer;
etching the second metal layer to remove portions of the second metal not covered by the switch region photoresist and the data line photoresist;
etching the semiconductor layer;
etching edge portions of the semiconductor in the switch region and the data line region;
etching the switch region photoresist layer and the data line region photoresist layer.

16. The method according to claim 15, characterized in that: a range of a ratio of the thickness of the switch region photoresist to the thickness of the data line region photoresist is greater than or equal to 11:10 and less than or equal to 11:5.

17. The method according to claim 15, characterized in that: etching edge portions of the semiconductor in the switch region and the data line region and etching the switch region photoresist layer and the data line region photoresist layer comprises:
using oxygen and fluoride-bearing gas to etch the switch region photoresist layer and the data line region photoresist layer as well as the edge portions of the semiconductor in the switch region and the data line region at the same time.
